(19) United States
(12) Patent Application Publication
(10) Pub. No.: US 2025/0140534 A1
(43) Pub. Date: May 1, 2025

(54) SUBSTRATE PROCESSING APPARATUS AND SUBSTRATE PROCESSING METHOD

(71) Applicant: SEMES CO., LTD., Cheonan-si (KR)

(72) Inventors: Young Seo AN, Cheonan-si (KR); Sang Man PARK, Goyang-si (KR); Han Lim KANG, Cheonan-si (KR); In Hoe KIM, Hwaseong-si (KR); Yoon Seok CHOI, Cheonan-si (KR); Sung Suk WI, Cheonan-si (KR); Tae Hun KANG, Cheonan-si (KR)

(73) Assignee: SEMES CO., LTD., Cheonan-si (KR)

(21) Appl. No.: 18/826,150

(22) Filed: Sep. 5, 2024

(30) Foreign Application Priority Data
Oct. 26, 2023 (KR) 10-2023-0144926

(51) Int. Cl. H01J 37/32

(52) U.S. Cl. CPC H01J 37/32724; H01J 37/32229; H01J 37/32238; H01J 37/32449; H01J 2237/20235; H01J 2237/334

(57) ABSTRACT

Disclosed are a substrate processing apparatus and a substrate processing method. The substrate processing apparatus includes a chamber including a processing space defined therein, a substrate support unit configured to support a substrate in the processing space, a microwave unit configured to supply microwaves to the processing space, a window member disposed below the microwave unit and configured to transmit the microwaves supplied from the microwave unit, a heat transfer plate disposed in the processing space so as to be spaced a predetermined distance from the window member and configured to be heated by the microwaves supplied to the processing space and to transfer heat to the substrate, and a controller configured to control the microwave unit.

### CROSS-REFERENCE TO RELATED APPLICATION(S)

This application claims priority under 35 U.S.C. § 119 to Korean Patent Application No. 10-2023-0144926, filed on Oct. 26, 2023 in the Korean Intellectual Property Office, the disclosure of which is incorporated by reference herein in its entirety.

### BACKGROUND OF THE INVENTION

### Field of the Invention

The present invention relates to a substrate processing apparatus and a substrate processing method. More particularly, the present invention relates to a substrate processing apparatus for evenly heating a substrate using microwaves.

### Description of the Related Art

In general, semiconductor chips are manufactured through a series of processes, for example, a process of depositing a thin film on the surface of a substrate, an etching process, a cleaning process, and a drying process. During these processes, the substrate needs to satisfy optimal conditions for implementation of each process. For example, the etching or deposition process is implemented through a physical or chemical method. The substrate may be heated to an appropriate temperature in order to activate reaction between the substrate and an etchant or a material for deposition.

Among various methods of increasing the temperature of a substrate, a substrate processing apparatus using plasma employs a method of increasing the temperature of a substrate using a heating means (heating wire) of a substrate support unit on which the substrate is placed. In the case of the conventional substrate heating method using a heater, it takes a long time to increase and lower temperature, and it is difficult to evenly heat the entirety of a substrate.

As a conventional method for solving this problem, a method of heating a substrate using a microwave unit in an upper side of a chamber has been proposed.

FIG. 1 is a view schematically showing a conventional substrate processing apparatus.

As shown in FIG. 1, the substrate processing apparatus 1 may include a chamber 100, a substrate support unit 200, a window member 310, and a microwave unit 500. When a substrate W is heated using the microwave unit 500, the substrate W is raised using a lift pin 252 provided in the substrate support unit 200, and microwaves generated by the microwave unit 500 pass through the window member 310 and reach the substrate W, thereby heating the substrate W. This method shortens a time required for heating, but has a problem in that there is a temperature difference between regions of the substrate W because the microwaves do not evenly reach the entire surface of the substrate W. In detail, because the microwaves first reach a peripheral region W2 of the substrate W, the peripheral region W2 of the substrate W is first heated, and then a central region W1 of the substrate W is heated. Accordingly, the temperature of the peripheral region W2 of the substrate W and the temperature of the central region W1 of the substrate W differ from each other, causing defects in a semiconductor chip and leading to reduction in yield.

Therefore, there is a demand for new technology for evenly transmitting microwaves generated by a microwave unit to the entire surface of a substrate.

### SUMMARY OF THE INVENTION

The present invention has been made to solve the above problems, and it is an object of the present invention to provide a substrate processing apparatus including a microwave unit and a substrate processing method capable of transmitting microwaves supplied to a processing space in a chamber to a substrate, thereby improving temperature uniformity of the entire surface of the substrate.

The objects to be accomplished by the invention are not limited to the above-mentioned object, and other objects not mentioned herein will be clearly understood by those skilled in the art from the following description.

In accordance with an aspect of the present invention, the above and other objects can be accomplished by the provision of a substrate processing apparatus including a chamber including a processing space defined therein, a substrate support unit configured to support a substrate in the processing space, a microwave unit configured to supply microwaves to the processing space, a window member disposed below the microwave unit and configured to transmit the microwaves supplied from the microwave unit, a heat transfer plate disposed in the processing space so as to be spaced a predetermined distance from the window member and configured to be heated by the microwaves supplied to the processing space and to transfer heat to the substrate, and a controller configured to control the microwave unit.

In one embodiment, the heat transfer plate may include a central region and a peripheral region formed along an outer peripheral surface of the central region, and the peripheral region of the heat transfer plate may include an opening formed therein to allow the microwaves to pass therethrough.

In one embodiment, the heat transfer plate may be made of a material including silicon or may be coated with silicon.

In one embodiment, the microwave unit may include a power supply configured to generate the microwaves and a ring-shaped waveguide configured to transmit the microwaves to the processing space in the chamber.

In one embodiment, the waveguide may include a plurality of slots formed in an inner periphery thereof, and the plurality of slots may be disposed so as to be spaced apart from each other at regular intervals along the inner periphery of the waveguide.

In one embodiment, the central region of the heat transfer plate may include at least one hole formed therein.

In one embodiment, the window member may include an upper electrode to generate plasma in the processing space.

In one embodiment, the upper electrode may be a transparent electrode.

In one embodiment, the substrate support unit may include a lift pin to raise and lower the substrate, and the controller may control operation of the lift pin so as to raise the substrate while driving the microwave unit.

In accordance with another aspect of the present invention, there is provided a substrate processing method of etching a thin film formed on a substrate, the substrate processing method including a modifying step of supplying a modifying gas to a processing space in a chamber accommodating the substrate to modify the substrate, a first purging step of supplying a purge gas to the processing space to remove the modifying gas remaining in the processing space, an etching step of supplying microwaves to the processing space and transferring heat from a heat transfer plate heated by the supplied microwaves to the substrate to etch the modified substrate in units of atomic layers, and a second purging step of supplying a purge gas to the processing space to remove etching by-products remaining in the processing space.

In one embodiment, a cycle including the modifying step to the second purging step may be repeatedly performed one or more times.

In one embodiment, the heat transfer plate may include a central region and a peripheral region formed along an outer peripheral surface of the central region, and the peripheral region of the heat transfer plate may include an opening formed therein to allow the microwaves to pass therethrough.

In one embodiment, in the etching step, the modified substrate may be moved to a position below the heat transfer plate using a lift pin.

In one embodiment, the etching step may be performed at a temperature of 300° C. or higher.

In one embodiment, in the modifying step, the modifying gas supplied to the processing space may be converted into plasma, and in the etching step, only microwaves may be supplied to the processing space.

In accordance with still another aspect of the present invention, there is provided a substrate processing apparatus including a chamber including a processing space defined therein, a substrate support unit including a lift pin to support a substrate in the processing space, a gas supply unit configured to supply gas to the processing space, a plasma generation unit configured to convert the supplied gas into plasma, a microwave unit configured to supply microwaves to the processing space, a window member disposed below the microwave unit and configured to transmit the microwaves supplied from the microwave unit, a heat transfer plate disposed in the processing space so as to be spaced a predetermined distance from the window member and configured to be heated by the microwaves supplied to the processing space and to transfer heat to the substrate, and a controller configured to control the plasma generation unit, the gas supply unit, and the microwave unit, wherein the heat transfer plate includes a central region and a peripheral region formed along an outer peripheral surface of the central region, the central region of the heat transfer plate includes at least one hole formed therein, the peripheral region of the heat transfer plate includes an opening formed therein, and the microwaves supplied by the microwave unit are transmitted to the central region of the heat transfer plate to heat the central region and are supplied to the substrate through the opening in the peripheral region of the heat transfer plate to heat the substrate.

In one embodiment, the controller may perform control such that the gas supply unit is not driven while the microwave unit is driven.

In one embodiment, the plasma supply unit may convert the gas supplied by the gas supply unit into plasma, and the gas converted into plasma may pass through the at least one hole in the central region of the heat transfer plate and the opening in the peripheral region of the heat transfer plate to be supplied to the substrate.

In one embodiment, the heat transfer plate may be made of a material including silicon or may be coated with silicon.

In one embodiment, the substrate processing apparatus may be an apparatus configured to etch the substrate.

### BRIEF DESCRIPTION OF THE DRAWINGS

The above and other objects, features, and other advantages of the present invention will be more clearly understood from the following detailed description taken in conjunction with the accompanying drawings, in which:

FIG. 1 is a view showing a conventional substrate processing apparatus;

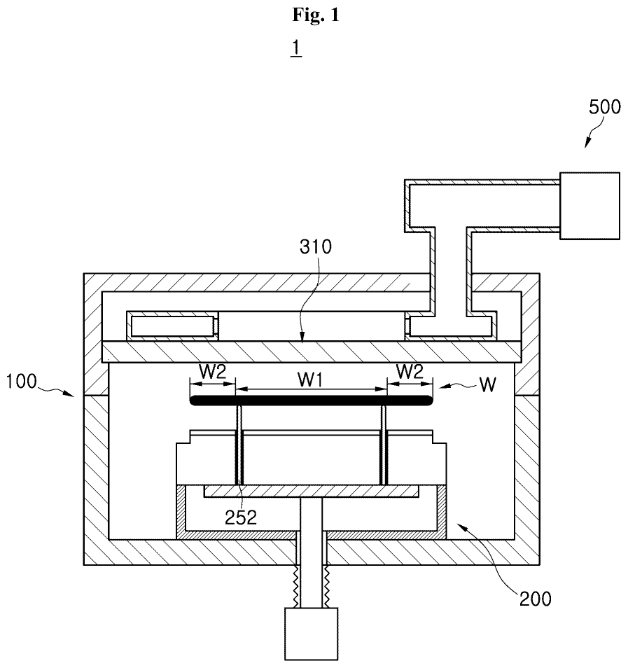

FIG. 2 is a view showing a substrate processing apparatus according to an embodiment of the present invention;

FIG. 3 is a view showing a window member according to an embodiment of the present invention;

FIG. 4 is a view showing a waveguide according to an embodiment of the present invention;

FIG. 5 is a view showing a heat transfer plate according to an embodiment of the present invention; and

FIG. 6 is a flowchart showing a substrate processing method according to an embodiment of the present invention.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

In the following description of the embodiments of the present invention, a detailed description of known functions or configurations incorporated herein will be omitted when it may unnecessarily obscure the subject matter of the present invention. Throughout the drawings, parts performing similar functions and operations are denoted by the same reference numerals.

At least some of the terms used in this specification are terms defined taking into consideration the functions obtained in accordance with the present invention, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present invention will be described in detail with reference to the accompanying drawings, and the same or similar elements are denoted by the same reference numerals even though they are depicted in different drawings, and redundant descriptions thereof will be omitted.

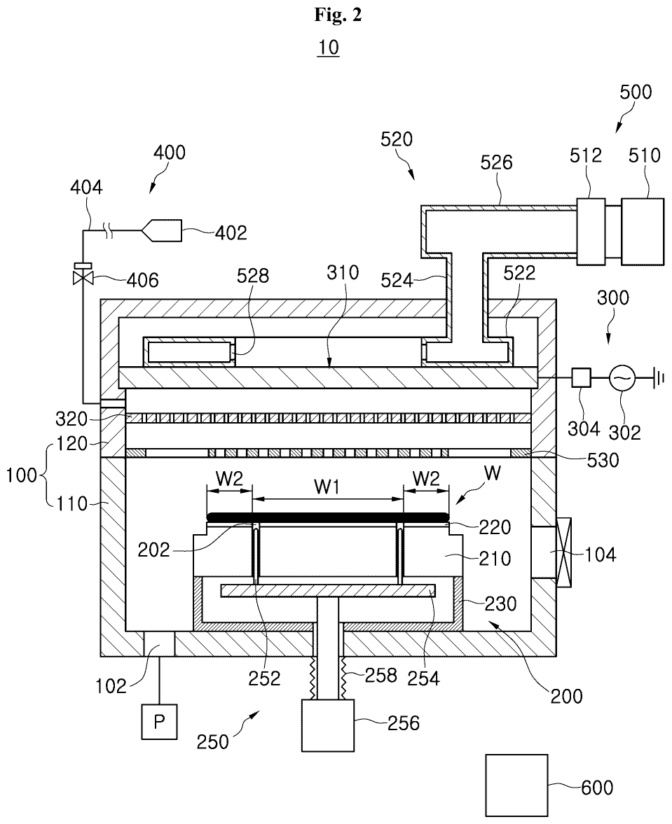

FIG. 2 is a view showing a substrate processing apparatus according to an embodiment of the present invention.

Referring to FIG. 2, the substrate processing apparatus 10 may include a chamber 100, a substrate support unit 200, a plasma generation unit 300, a gas supply unit 400, a microwave unit 500, and a controller 600.

The chamber 100 may have a processing space defined therein so as to allow a plasma process to be performed therein, and may include a body 110 and a cover 120. The body 110 may have an open upper surface and may have an inner space defined therein. In one example, the body 110 may have a cylindrical shape having an open upper surface and having an inner space defined therein. The cover 120 may be provided on the upper end of the body 110. The cover 120 may seal the open upper surface of the body 110. In one example, the cover 120 may have a cylindrical shape having an open lower surface. The body 110 and the cover 120 may be assembled to each other to form the chamber 100.

The chamber 100 may include an exhaust port 102 formed in a lower side thereof, and the exhaust port 102 may be connected to an exhaust line on which a pump P is mounted. The pump P may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in the sidewall thereof. The opening 104 may function as a passage through which a substrate W enters the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

The substrate support unit 200 may include a support body 210 and an electrostatic chuck 220 disposed on the upper surface of the support body 210. The electrostatic chuck 220 may be configured to electrostatically attract and hold the substrate W, and may include a ceramic layer provided with an electrode.

According to an embodiment of the present invention, although not shown, the substrate support unit 200 may be provided therein with a heating member and a cooling member to maintain the substrate W at a process temperature. The heating member may be a heating coil, and the cooling member may be provided as a cooling line through which refrigerant flows.

A pedestal 230 may be provided under the support body 210 in order to support the support body 210 and the electrostatic chuck 220. The pedestal 230 may be formed in a cylindrical shape having a predetermined height, and may have a space defined therein. A lift pin assembly 250 may be provided in the pedestal 230.

The lift pin assembly 250 according to an embodiment of the present invention may include a lift pin 252, a lift pin support member 254, a lift pin driving unit 256, and a bellows 258.

The substrate support unit 200 may include a plurality of lift pins 252 disposed at regular intervals in order to load and unload the substrate W. The substrate support unit 200 may include a plurality of pin holes 202 vertically penetrating the substrate support unit 200 to allow the lift pins 252 to move vertically therethrough.

The lift pin 252 may be provided in plural, and each of the plurality of lift pins 252 may be received in a respective one of the pin holes 202 formed in the substrate support unit 200. The diameter of the lift pin 252 may be formed to be slightly smaller than the diameter of the pin hole 202.

The lift pins 252 may be inserted into and fixed in lift pin holders (not shown). The number of lift pin holders (not shown) may be identical to the number of lift pins 252, and the lift pin holders (not shown) may be coupled and fixed to the lift pin support member 254.

The lift pin support member 254 may be provided in the chamber 100, and may support the lift pins 252 and the lift pin holders (not shown). The lift pin support member 254 may be formed in a plate shape in order to support the plurality of lift pins 252 and the plurality of lift pin holders (not shown). However, this embodiment is not limited thereto. The lift pin support member 254 may be connected to the lift pin driving unit 256, and may be moved vertically by the lift pin driving unit 256.

The lift pin driving unit 256 may raise and lower the lift pin support member 254. Due to operation of the lift pin driving unit 256, the lift pin support member 254 may move vertically, and accordingly, the lift pins 252 may move along the pin holes 202. The lift pin driving unit 256 may be disposed outside the chamber 100. The lift pin driving unit 256 may employ a hydraulic cylinder, a pneumatic cylinder, or the like. However, this embodiment is not limited thereto. Although the embodiment of the present invention is described as including one lift pin driving unit 256, this embodiment is not limited thereto. The lift pin driving unit 256 may be provided in plural in order to raise and lower respective lift pins 252.

The bellows 258 may be provided on a portion of the lift pin driving unit 256 that extends to the outside of the chamber 100. The bellows 258 may have a structure capable of expanding and contracting, and may be provided to surround the lift pin driving unit 256. Accordingly, the inside of the chamber 100 may be blocked from the outside, and thus the vacuum state in the chamber 100 may be maintained even when the lift pin support member 254 moves vertically.

The plasma generation unit 300 may generate plasma in the processing space in the chamber 100. Plasma may be generated in an area above the substrate support unit 200 in the chamber 100. According to an embodiment of the present invention, the plasma generation unit 300 may generate plasma in the processing space in the chamber 100 using a capacitively coupled plasma (CCP) source.

However, this embodiment is not limited thereto. The plasma generation unit 300 may also generate plasma in the processing space in the chamber 100 using another type of plasma source, such as an inductively coupled plasma (ICP) source or microwaves.

The plasma generation unit 300 may include a high-frequency power supply 302 and a matching device 304. The high-frequency power supply 302 may supply high-frequency power to any one of an upper electrode and a lower electrode in order to generate a potential difference between the upper electrode and the lower electrode. Here, the upper electrode may be provided in a window member 310 to be described later, and the lower electrode may be the substrate support unit 200. The high-frequency power supply 302 may be connected to the upper electrode 312 provided in the window member 310, and the lower electrode may be grounded (not shown).

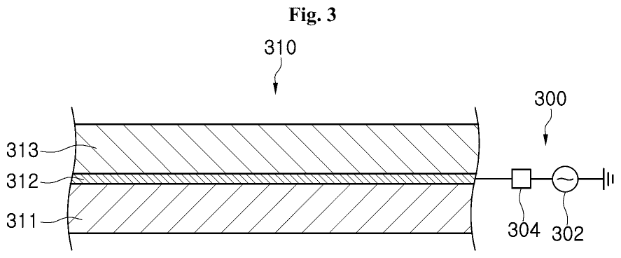

FIG. 3 is a view showing a window member according to an embodiment of the present invention.

Referring to FIG. 3, the window member 310 according to an embodiment of the present invention may include a first window 311, an upper electrode 312, and a second window 313. The window member 310 may be configured to allow microwaves generated by the microwave unit 500, which will be described later, to be transmitted to the substrate W without loss (or with minimized loss).

The upper electrode 312 may be stacked on the first window 311. The upper electrode 312 may be formed to have a thickness that allows microwaves for heating the substrate W to pass therethrough. In an example, the upper electrode 312 may be a transparent electrode, and may be ITO. Alternatively, the upper electrode 312 may include AZO, FTO, ATO, SnO₂, ZnO, IrO₂, RuO₂, graphene, metal nanowires, CNTs, mixtures thereof, or multiple layers thereof. The upper electrode 312 may be formed to have a first thickness or less. The first thickness is a thickness that allows microwaves to pass through a determined material. The first thickness may vary depending on the material selected as the upper electrode 312. In this description, the thickness that allows microwaves to pass through a determined material may be a thickness that does not greatly affect the transmittance of the determined material. In an example, if the upper electrode 312 is made of ITO, the first thickness may be set to 1 μm or less. The upper electrode 312 and the substrate support unit 200 may be combined to generate an electric field due to high-frequency power applied from the high-frequency power supply 302 to at least one thereof. In an example, high-frequency power may be applied to the upper electrode 312 by the high-frequency power supply 302, and the substrate support unit 200 may be grounded (not shown).

The first window 311 may be made of a material that allows microwaves for heating the substrate W to pass therethrough, and may be made of a corrosion-resistant material. The first window 311 according to an embodiment of the present invention may be quartz.

The second window 313 may be stacked on the upper electrode 312. The second window 313 may be made of a material that allows microwaves for heating the substrate W to pass therethrough, and may be, for example, quartz.

Referring again to FIG. 2, a shower head 320 may be provided in the chamber 100 so as to be spaced a predetermined distance from the window member 310 and to vertically oppose the electrostatic chuck 220. The shower head 320 may include a plurality of gas spray holes formed therein in order to evenly spray gas to the inside of the chamber 100, and may be formed to have a larger diameter than the electrostatic chuck 220. The microwave unit 500 may be provided above the shower head 320 in order to rapidly increase the temperature of the substrate W. In this case, the shower head 320 may be made of a transparent material in order to allow microwaves supplied from the microwave unit 500 to pass therethrough and to be transmitted to the substrate W. Although the shower head 320 is illustrated in FIG. 2 as being disposed between a heat transfer plate 530 and the window member 310, this embodiment is not limited thereto.

The gas supply unit 400 may supply gas necessary for the process to the inside of the chamber 100. The gas supply unit 400 may include a gas source 402, a gas supply line 404, and a gas spray nozzle. The gas supply line 404 may connect the gas source 402 to the gas spray nozzle. The gas supply line 404 may supply gas stored in the gas source 402 to the gas spray nozzle. A gas supply valve 406 may be mounted on the gas supply line 404 in order to open and close the passage of the gas supply line 404 or to regulate the amount of fluid flowing through the passage.

Although one gas source 402 and one gas supply valve 406 are illustrated in FIG. 2, the gas supply unit of the present invention may include a plurality of gas sources to supply a plurality of gases to the chamber and a plurality of gas supply valves to independently control supply of the respective gases.

The microwave unit 500 may apply microwaves to the processing space in the chamber 100. The microwave unit 500 may include a power supply 510 and a waveguide 520.

The power supply 510 may include a matching network 512. The power supply 510 may serve to generate microwaves, and the generated microwaves may have a frequency of about 2.3 GHz to about 2.5 GHz. The power supply 510 may be connected to the waveguide 520, and the matching network 512 may be disposed between the power supply 510 and the waveguide 520. The matching network 512 may match the microwaves supplied from the power supply 510 to a predetermined frequency.

The waveguide 520 may be formed in a tube shape having a polygonal or circular section. The waveguide 520 may include a conductive inner surface. In an example, the inner surface of the waveguide 520 may be made of gold or silver. The waveguide 520 may provide a passage through which microwaves generated by the power supply 510 are transmitted.

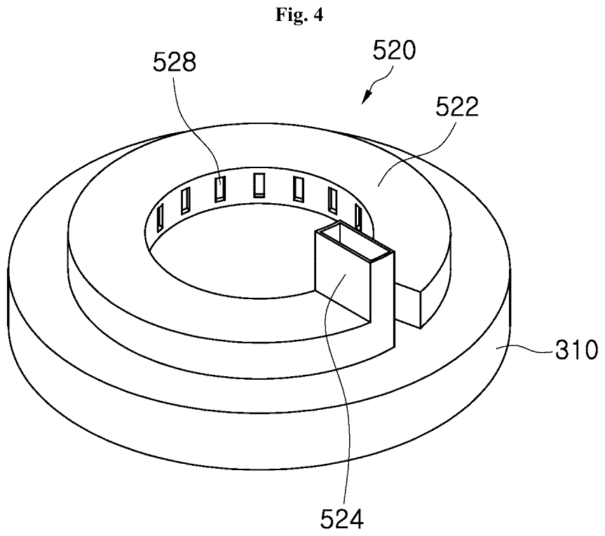

FIG. 4 is a view showing a waveguide according to an embodiment of the present invention.

Referring to FIGS. 2 and 4, the waveguide 520 according to an embodiment of the present invention may include a first portion 522, a second portion 524, and a third portion 526. The first portion 522, the second portion 524, and the third portion 526 may be integrally formed with each other.

The first portion 522 may be formed in a ring shape, and may include a cut portion. In addition, the first portion 522 may include a plurality of slots 528 formed in the inner periphery thereof. The slots 528 may be formed as through-slots penetrating the side surface of the first portion 522, and may be selectively filled with a material capable of transmitting microwaves. The slots 528 may have a rectangular shape elongated in the longitudinal direction of the waveguide 520. The plurality of slots 528 may be disposed so as to be spaced apart from each other at regular intervals along the inner periphery of the first portion 522.

The second portion 524 may extend from the first portion 522. In an example, the second portion 524 may extend upwardly from the upper surface of the first portion 522. The second portion 524 may be coupled to the upper surface of the first portion 522 at a position abutting the cut portion of the first portion 522.

The third portion 526 may extend from the second portion 524. In an example, the third portion 526 may extend in the horizontal direction from the upper surface of the second portion 524. The third portion 526 may be connected to the power supply 510.

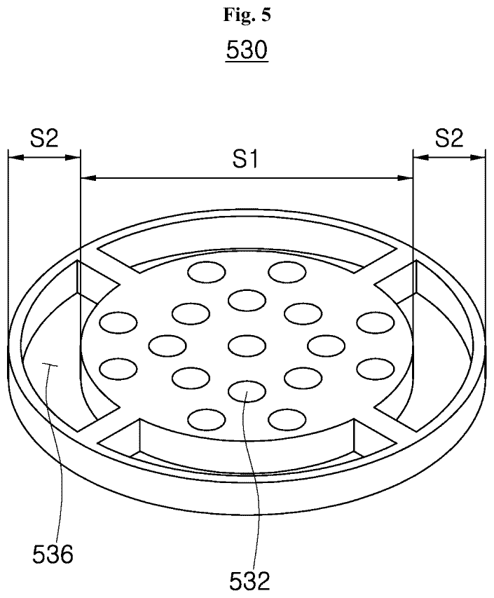

FIG. 5 is a view showing a heat transfer plate according to an embodiment of the present invention.

Referring to FIGS. 2 and 5, the heat transfer plate 530 according to an embodiment of the present invention may be disposed in the processing space in the chamber 100, and may be provided below the shower head 320. In another embodiment, the heat transfer plate 530 may be provided between the shower head 320 and the window member 310. The heat transfer plate 530 may serve to evenly transmit microwaves supplied from the microwave unit 500 to the substrate W. The heat transfer plate 530 may have a disc shape, and may include a central region S1 and a peripheral region S2 formed along the outer peripheral surface of the central region S1.

The heat transfer plate 530 may include a plurality of holes 532 formed in the central region S1 thereof. The holes 532 may have a predetermined size, and may allow gas converted into plasma by the plasma generation unit 300 to pass therethrough. In detail, the gas converted into plasma by the plasma generating unit 300 may be decomposed into ions, radicals, and electrons, and the decomposed ions, radicals, and electrons may pass through the holes 532 formed in the heat transfer plate 530 to be supplied to the substrate W. Although the holes 532 in the central region S1 of the heat transfer plate 530 according to the embodiment of the present invention are illustrated as having the same size, this embodiment is not limited thereto. In addition, a portion of the central region S1 of the heat transfer plate 530, not provided with the holes 532, may be heated by the microwaves supplied from the microwave unit 500, thereby transferring heat to the central region W1 of the substrate W.

The heat transfer plate 530 may include a plurality of openings 536 formed in the peripheral region S2 thereof. In an example, four openings 536 may be formed in the peripheral region S2, but this embodiment is not limited thereto. The openings 536 may not only supply the gas converted into plasma to the substrate W, but may also directly supply the microwaves supplied from the microwave unit 500 to the substrate W. The microwaves supplied from the microwave unit 500 may be supplied to the periphery of the substrate W to heat the peripheral region W2 of the substrate W.

The heat transfer plate 530 may be made of a material having corrosion resistance, plasma resistance, heat resistance, and high thermal conductivity. In an example, the heat transfer plate 530 may be made of a material containing silicon, or may be coated with silicon. The heat transfer plate 530 according to the embodiment of the present invention may be made of silicon carbide (SiC), but this embodiment is not limited thereto. Alternatively, the heat transfer plate 530 may also be made of a material capable of transmitting microwaves.

The controller 600 may comprehensively control the operation of the substrate processing apparatus 10 configured as described above. The controller 600 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the apparatus. In an example, the controller 600 may control the operation of the lift pin assembly 250, and may also control the supply operation of various gases by the gas supply unit 400 and the operation of the power supply 302 of the plasma generation unit 300. In addition, a computer-readable program necessary for control may be stored in a storage medium. The storage medium may include, for example, a flexible disk, a compact disc (CD), a CD-ROM, a hard disk, a flash memory, a DVD, or the like. The controller 600 may be provided inside or outside the substrate processing apparatus 10. In the case in which the controller 600 is provided outside the substrate processing apparatus 10, the controller 600 may control the substrate processing apparatus 10 using a wired or wireless communication method.

In order to perform the process, the controller 600 according to the embodiment of the present invention may perform control such that gas is supplied to the processing space in the chamber 100 and the supplied gas is converted into plasma by the plasma generation unit 300. In addition, the controller 600 may control the lift pin driving unit 256 to vertically move the lift pins 252 in order to load/unload the substrate W before/after performing heat treatment on the substrate W using the microwave unit 500.

As described above, since the heat transfer plate is provided in the processing space in the chamber, the entire surface of the substrate may be evenly heated. In more detail, the heat transfer plate may be provided below the shower head, and may supply microwaves supplied from the microwave unit to the substrate. The heat transfer plate may include a central region and a peripheral region formed along the outer peripheral surface of the central region. The central region of the heat transfer plate may include holes formed therein, and the peripheral region thereof may include openings formed therein. Gas converted into plasma may be supplied to the substrate through the holes formed in the central region and the openings formed in the peripheral region. In addition, the microwaves supplied from the microwave unit may be directly supplied to the peripheral region of the substrate through the openings formed in the peripheral region of the heat transfer plate, and a portion of the central region of the heat transfer plate, not provided with the holes, may be heated by the microwaves, thereby supplying heat to the central region of the substrate. Accordingly, the substrate may be evenly heated, leading to reduction in defects in a semiconductor chip and improvement in yield.

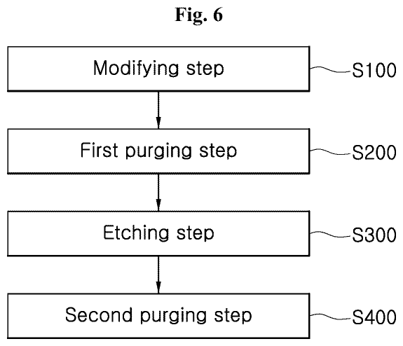

FIG. 6 is a flowchart showing a substrate processing method according to an embodiment of the present invention.

Referring to FIG. 6, a method of etching a thin film formed on a substrate according to an embodiment of the present invention may include a modifying step (S100) of supplying a modifying gas to a processing space in a chamber in which a substrate is disposed to modify the substrate, a first purging step (S200) of supplying a purge gas to the processing space to remove the modifying gas remaining in the processing space, an etching step (S300) of supplying microwaves to the processing space to etch the modified substrate in units of atomic layers, and a second purging step (S400) of supplying a purge gas to the processing space to remove etching by-products remaining in the processing space. The modifying step to the second purging step (S100 to S400) may be set as one cycle, and this cycle may be repeatedly performed one or more times to etch the substrate to a desired thickness.

The modifying step (S100) is a step of supplying a modifying gas to a processing space in a chamber in which a substrate is disposed to modify the substrate. The modifying gas may be supplied from a gas supply unit, and the supplied modifying gas may be converted into plasma and may then be supplied to the substrate. The modifying gas converted into plasma may cause chemical reaction with the substrate to modify the surface layer of the substrate.

The first purging step (S200) is a step of supplying, by the gas supply unit, a purge gas to remove the modifying gas remaining in the chamber. The purge gas may be supplied after the supply of the modifying gas is interrupted, and may be directly supplied to the processing space in the chamber without using plasma. Due to the supply of the purge gas, the modifying gas remaining in the chamber after being supplied in the modifying step (S100) and reaction by-products may be removed. An inert gas, such as argon (Ar), helium (He), or nitrogen (N₂), may be used as the purge gas.

The etching step (S300) is a step of supplying microwaves to the processing space in the chamber to etch the modified substrate in units of atomic layers. The modified substrate may be etched in units of atomic layers by supplying microwaves, i.e., heat, to the substrate using the microwave unit. According to an embodiment of the present invention, heat of 300° C. or higher may be supplied to the substrate using the microwave unit. In this case, the substrate may be raised by the lift pin assembly to be disposed adjacent to the heat transfer plate and to be disposed below the shower head. The microwaves supplied from the microwave unit may pass through the openings formed in the peripheral region of the heat transfer plate and may be supplied to the peripheral region of the substrate. In addition, the microwaves may heat the central region of the heat transfer plate, e.g., a portion of the central region of the heat transfer plate, not provided with holes, thereby transferring heat to the substrate. In this way, since the heat transfer plate is provided in the chamber, heat may be evenly supplied to the entire surface of the substrate, and the entire surface of the substrate may be evenly etched.

The second purging step (S400) is a step of supplying, by the gas supply unit, a purge gas to remove etching by-products remaining in the chamber. The purge gas may be supplied after the supply of the microwaves is interrupted, and may be directly supplied to the processing space in the chamber without using plasma. Due to the supply of the purge gas, etching by-products generated during the etching step (S300) may be removed. An inert gas, such as argon (Ar), helium (He), or nitrogen (N₂), may be used as the purge gas.

As is apparent from the above description, according to the present invention, a heat transfer plate may be provided in a processing space in a chamber, thereby improving temperature uniformity of the entire surface of a substrate.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

What is claimed is:

1. A substrate processing apparatus comprising:
a chamber comprising a processing space defined therein;
a substrate support unit configured to support a substrate in the processing space;
a microwave unit configured to supply microwaves to the processing space;
a window member disposed below the microwave unit, the window member being configured to transmit the microwaves supplied from the microwave unit into the processing space;
a heat transfer plate disposed in the processing space and spaced apart the window member in a predetermined distance, the heat transfer plate being configured to be heated by the microwaves supplied to the processing space and to transfer heat to the substrate; and
a controller configured to control the microwave unit.

2. The substrate processing apparatus according to claim 1, wherein the heat transfer plate comprises:
a central region; and
a peripheral region formed along an outer peripheral surface of the central region, and
wherein the peripheral region of the heat transfer plate comprises an opening formed therein to allow the microwaves to pass therethrough.

3. The substrate processing apparatus according to claim 1, wherein the heat transfer plate is made of a material comprising silicon or is coated with silicon.

4. The substrate processing apparatus according to claim 1, wherein the microwave unit comprises:
a power supply configured to generate the microwaves; and
a ring-shaped waveguide configured to transmit the microwaves to the processing space in the chamber.

5. The substrate processing apparatus according to claim 4, wherein the ring-shaped waveguide comprises a plurality of slots formed in an inner periphery thereof, and
wherein the plurality of slots is disposed so as to be spaced apart from each other at regular intervals along the inner periphery of the ring-shaped waveguide.

6. The substrate processing apparatus according to claim 2, wherein the central region of the heat transfer plate comprises at least one hole formed therein.

7. The substrate processing apparatus according to claim 1, wherein the window member comprises an upper electrode to generate plasma in the processing space.

8. The substrate processing apparatus according to claim 7, wherein the upper electrode is a transparent electrode.

9. The substrate processing apparatus according to claim 1, wherein the substrate support unit comprises a lift pin to raise and lower the substrate, and
wherein the controller controls operation of the lift pin so as to raise the substrate while driving the microwave unit.

10. A substrate processing method of etching a thin film formed on a substrate, the substrate processing method comprising:
a modifying step of supplying a modifying gas to a processing space in a chamber accommodating the substrate to modify the substrate;
a first purging step of supplying a purge gas to the processing space to remove the modifying gas remaining in the processing space;
an etching step of supplying microwaves to the processing space and transferring heat from a heat transfer plate heated by the supplied microwaves to the substrate to etch the modified substrate in units of atomic layers; and
a second purging step of supplying a purge gas to the processing space to remove etching by-products generated in the etching step and remaining in the processing space.

11. The substrate processing method according to claim 10, wherein a cycle comprising the modifying step to the second purging step is repeatedly performed one or more times.

12. The substrate processing method according to claim 10, wherein the heat transfer plate comprises:
a central region; and
a peripheral region formed along an outer peripheral surface of the central region, and
wherein the peripheral region of the heat transfer plate comprises an opening formed therein to allow the microwaves to pass therethrough.

13. The substrate processing method according to claim 10, wherein, in the etching step, the modified substrate is moved to a position below the heat transfer plate using a lift pin.

14. The substrate processing method according to claim 10, wherein the etching step is performed at a temperature of 300° C. or higher.

15. The substrate processing method according to claim 10, wherein, in the modifying step, the modifying gas supplied to the processing space is converted into plasma, and wherein, in the etching step, only microwaves are supplied to the processing space.

16. A substrate processing apparatus comprising:
a chamber comprising a processing space defined therein;
a substrate support unit comprising a lift pin to support a substrate in the processing space;
a gas supply unit configured to supply gas to the processing space;
a plasma generation unit configured to convert the supplied gas into plasma;
a microwave unit configured to supply microwaves to the processing space;
a window member disposed below the microwave unit, the window member being configured to transmit the microwaves supplied from the microwave unit;
a heat transfer plate disposed in the processing space so as to be spaced a predetermined distance from the window member, the heat transfer plate being configured to be heated by the microwaves supplied to the processing space and to transfer heat to the substrate; and
a controller configured to control the plasma generation unit, the gas supply unit, and the microwave unit,
wherein the heat transfer plate comprises:
a central region; and
a peripheral region formed along an outer peripheral surface of the central region,
wherein the central region of the heat transfer plate comprises at least one hole formed therein,
wherein the peripheral region of the heat transfer plate comprises an opening formed therein, and
wherein the microwaves supplied by the microwave unit are transmitted to the central region of the heat transfer plate to heat the central region and are supplied to the substrate through the opening in the peripheral region of the heat transfer plate to heat the substrate.

17. The substrate processing apparatus according to claim 16, wherein the controller performs control such that the gas supply unit is not driven while the microwave unit is driven.

18. The substrate processing apparatus according to claim 16,
wherein the supplied gas converted into plasma passes through the at least one hole in the central region of the heat transfer plate and the opening in the peripheral region of the heat transfer plate to be supplied to the substrate.

19. The substrate processing apparatus according to claim 16, wherein the heat transfer plate is made of a material comprising silicon or is coated with silicon.

20. The substrate processing apparatus according to claim 16, wherein the substrate processing apparatus is an apparatus configured to etch the substrate.
